(19) United States
(12) Patent Application Publication
(10) Pub. No.: US 2021/0005636 A1
(43) Pub. Date: Jan. 7, 2021

(54) RESIN FILM, DISPLAY COMPRISING SAME, AND PRODUCTION METHODS FOR SAME

(71) Applicant: Toray Industries, Inc., Chuo-ku (JP)

(72) Inventors: Tomoki Ashibe, Otsu-shi, Shiga (JP); Daichi Miyazaki, Otsu-shi, Shiga (JP)

(73) Assignee: Toray Industries, Inc., Tokyo (JP)

(21) Appl. No.: 16/979,284

(22) PCT Filed: Mar. 22, 2019
(86) PCT No.: PCT/JP2019/012183

§ 371 Date: Sep. 9, 2020

(30) Foreign Application Priority Data
Mar. 29, 2018 (JP) 2018-064030

(51) Int. Cl. H01L 27/12

(52) U.S. Cl. CPC H01L 27/1218; H01L 27/1262

(57) ABSTRACT

A resin film used as a support substrate of a thin film transistor is described where the resin film contains a heat-resistant resin and a predetermined face of the resin film has a sheet resistance of more than 1×10¹²Ω and less than 1×10¹⁶Ω. The resin film is less likely to have foreign substances stuck thereto, and thus, can inhibit damage caused to a TFT element by gas emitted from foreign substances in high-temperature processes. The resin film can also be provided as a support substrate of a thin film transistor in a display.

### CROSS REFERENCE TO RELATED APPLICATIONS

This is the U.S. National Phase application of PCT/JP2019/012183, filed Mar. 22, 2019, which claims priority to Japanese Patent Application No. 2018-064030, filed Mar. 29, 2018, the disclosures of these applications being incorporated herein by reference in their entireties for all purposes.

### FIELD OF THE INVENTION

The present invention relates to resin films, displays including the same, and methods of producing such resin films and displays.

### BACKGROUND OF THE INVENTION

Heat-resistant resins such as polyimide, polybenzoxazole, polybenzothiazole, and polybenzimidazole have been used as materials for various electronic devices. Recently, production of shock resistant and flexible displays has become possible by using resin films for the substrates of displays such as organic EL displays, electronic paper, and color filters. In particular, thin film transistors (TFTs) for displays need high-temperature treatment in production processes, and thus, development has been encouraged to use a resin film of a heat-resistant resin for the support substrate of such a TFT.

A resin film used for a TFT support substrate is a resin film having high insulation properties in addition to high heat resistance. For example, Patent Literature 1 reports an example in which TFTs having excellent reliability are produced using a resin substrate having a volume resistivity of 1×10¹⁷ [Ω·cm] or more as a TFT substrate.

### PATENT LITERATURE

Patent Literature 1: JP2017-221360A

### SUMMARY OF THE INVENTION

However, the resin film described in Patent Literature 1 poses a problem in that foreign substances tend to stick onto the film. In particular, in production processes of TFTs, resin films used for support substrates of TFTs pass through high-temperature processes, and thus, a slight amount of gas emitted from the foreign substances stuck onto the resin films destroys the TFT elements and will undesirably cause a pixel defect. This poses a problem, that is, lowers the yield rate of the TFT production.

In view of the above-mentioned problems, the present invention has been made, and an object thereof is to provide: a resin film suitable for TFT support substrates; a display containing such a resin film; and a method of producing such a resin film and display; wherein the resin film is less likely to have foreign substances stuck thereto and can enhance the yield rate of the TFT production.

To solve the above-mentioned problems and achieve the object, a resin film according to the present invention is a resin film to be used as a support substrate of a thin film transistor and is characterized by including a heat-resistant resin, wherein a predetermined resin film face of the resin film has a sheet resistance of more than 1×10¹²Ω and less than 1×10¹⁶Ω.

In addition, the resin film according to the present invention is characterized in that, in the above-mentioned invention, the resin film further contains electroconductive particles.

In addition, the resin film according to the present invention is characterized in that, in the above-mentioned invention, the electroconductive particles are carbon particles.

In addition, the resin film according to the present invention is characterized in that, in the above-mentioned invention, the amount of the electroconductive particles is 0.01 parts by mass or more and 3 parts by mass or less with respect to 100 parts by mass of the heat-resistant resin.

In addition, the resin film according to the present invention is characterized in that, in the above-mentioned invention, the resin film has a film thickness of 4 μm or more and 40 μm or less.

In addition, the resin film according to the present invention is characterized in that, in the above-mentioned invention, the predetermined resin film face has an arithmetic mean roughness of 10 nm or less.

In addition, a display according to the present invention is characterized by including the resin film according to any one of the above-mentioned inventions.

In addition, a method of producing a resin film according to the present invention is a resin film production method which produces the resin film according to any one of the above-mentioned inventions, and is characterized by including: a coating step of coating a support with a resin composition containing a heat-resistant resin or a precursor of the heat-resistant resin and a solvent; and a heating step of heating a coating film obtained by the coating step, to obtain a resin film.

In addition, the method of producing a resin film according to the present invention is characterized in that, in the above-mentioned invention, the method includes a polishing step of polishing the heated resin film.

In addition, the method of producing a resin film according to the present invention is characterized in that, in the above-mentioned invention, the method includes an irradiating step of irradiating the heated resin film with a laser.

In addition, the method of producing a resin film according to the present invention is characterized in that, in the above-mentioned invention, the method includes: a resist coating step of coating the heated resin film with a resist to form a laminate of the resin film on the support and the resist covering the resin film; and an etching step of dry-etching the resist-coated side of the obtained laminate to expose the resin film.

In addition, the method of producing a display according to the present invention is characterized by including: a film-producing step of producing a resin film on a support by the method of producing a resin film according to any one of the above-mentioned inventions; an element-forming step of forming a thin film transistor element on the resin film; and a detaching step of detaching, from the support, the resin film having the thin film transistor element formed thereon.

The present invention can provide a resin film that is less likely to have foreign substances stuck thereto and is suitable for TFT support substrates. In high-temperature processes in TFT production, such a resin film also makes it possible to inhibit damage from being caused to a TFT element by gas emitted from foreign substances, and thus, to enhance the yield rate of the TFT production.

### DETAILED DESCRIPTION OF EMBODIMENTS OF THE INVENTION

Below, embodiments of the present invention will be described in detail. However, the present invention is not limited to the following embodiments, but can be embodied with various changes in accordance with the purposes and applications.

<Resin Film>

A resin film according to an embodiment of the present invention is a resin film used as a support substrate of a thin film transistor (TFT) and contains a heat-resistant resin. A predetermined resin film face of the resin film has a sheet resistance of more than 1×10¹²Ω and less than 1×10¹⁶Ω. For example, the predetermined resin film face is one of both sides (both front and rear sides) of the resin film in the film thickness direction. The resin film preferably has a TFT formed on that face of both the resin film faces in the film thickness direction which has a sheet resistance in the above-mentioned range. Hereinafter, a “resin film” refers to a resin film according to an embodiment of the present invention, unless otherwise specified. In addition, that resin film face of both resin film faces of the resin film in the film thickness direction which is the side having a TFT formed thereon is referred to as a “TFT-formed face”. For example, in forming a resin film on a support before forming a TFT, the face of the resin film opposite from the face in contact with the support is the TFT-formed face.

A resin film having a sheet resistance of less than 1×10¹⁶Ω on a predetermined face of the resin film makes it possible to decrease foreign substances sticking to the resin film. In high-temperature processes in TFT production, such a resin film also makes it possible to inhibit damage from being caused to a TFT element by gas emitted from foreign substances, and thus, to enhance the yield rate of the TFT production. A resin film having an excessively large sheet resistance (for example, 1×10¹⁶Ω or more) makes it more likely that the resin film is electrically charged, resulting in causing a Coulomb force to act between the resin film and foreign substances. This makes foreign substances tend to stick onto the resin film face. The inference here is that, if the above-mentioned sheet resistance is less than 1×10¹⁶Ω, the diffusion and recombination of electric charge decreases the charge density of the resin film face, resulting in decreasing the Coulomb force between the resin film and foreign substances and thus making it possible to decrease foreign substances sticking to the resin film. In particular, the sheet resistance is preferably less than 1×10¹⁵Ω from the viewpoint of decreasing foreign substances sticking to the resin film.

In addition, a resin film having the sheet resistance of more than 1×10¹²Ω makes it possible to prevent the TFT from malfunctioning owing to leak between the TFT wirings. In particular, the sheet resistance is preferably more than 1×10¹³Ω, more preferably more than 1×10¹⁴Ω, from the viewpoint of preventing the TFT from malfunctioning. In the present invention, another preferable example is a range into which the above-mentioned upper limit values and lower limit values for the sheet resistance of a resin film are combined arbitrarily. Accordingly, for example, more than 1×10¹³Ω and less than 1×10¹⁶Ω is also a preferable range for the sheet resistance.

Examples of methods of bringing the sheet resistance of a resin film within the above-mentioned range include a method in which an additive is added to a resin film containing a heat-resistant resin. Examples of additives include ionic compounds, electroconductive particles, and the like. Among these, a resin film according to an embodiment of the present invention preferably further contains electroconductive particles as an additive in addition to the heat-resistant resin. Electroconductive particles as an additive make it possible to regulate the sheet resistance of a resin film to a desired value without decreasing the heat resistance of the resin film.

In this regard, the sheet resistance in the present invention is a value measured by the guarded-electrode system in accordance with the Japanese Industrial Standards (JIS K 6271:2015). An electrode used for the measurement is produced from silver paste, wherein the main electrode diameter is 37 mm, the ring electrode width is 5.5 mm, the distance between the main electrode and the ring electrode is 1 mm, and the counter electrode diameter is 55 mm. A voltage to be applied in the measurement is 500 V.

(Electroconductive Particles)

Electroconductive particles in the present invention are, without particular limitation, particles having electrical conductivity. Examples of electroconductive particles include carbon particles, metal particles, metal oxide particles, and the like. Examples of carbon particles include particles of carbon black, carbon nanotube, carbon fiber, graphene, and the like. Examples of metal particles include particles of gold, aluminium, copper, indium, antimony, magnesium, chromium, tin, nickel, silver, iron, titanium, alloy thereof, and the like. Examples of metal oxide particles include particles of yttrium oxide, indium oxide, tin oxide, composite oxide thereof, and the like. These electroconductive particles may be used singly or in combination of two or more kinds thereof.

Among these, the electroconductive particles are preferably carbon particles, more preferably carbon black. As explained below, such carbon particles as the electroconductive particles make it possible to prevent the reliability of the TFT from being degraded. In general, a TFT is driven by electric current run between a source electrode and a drain electrode by causing a semiconductor layer to be activated by applying a voltage equal to or greater than the threshold voltage to a gate electrode. At this time, in a case where a resin film to be used as a support substrate contains an electric charge, an electrical field derived from the electric charge affects the semiconductor layer, and thus, can induce a variation in the threshold voltage. Carbon particles used as the electroconductive particles make it possible to prevent the amount of electric charge in a resin film from changing, and thus, make it possible to prevent the threshold voltage from varying.

In the present invention, the electroconductive particle is not limited to any particular shape, and may have a desired shape. Examples of the shape of the electroconductive particle include a spherical shape, elliptic shape, flat shape, rod-like shape, fibrous shape, and the like.

The average particle diameter of the electroconductive particles is not limited to any particular value, and is preferably 0.01 μm or more, more preferably 0.02 μm or more. In addition, the average particle diameter of the electroconductive particles is preferably 10 μm or less, more preferably 1 μm or less. The electroconductive particles having an average particle diameter of 0.01 μm or more make it possible that the sheet resistance of a resin film is controlled by adding the electroconductive particles. The electroconductive particles having an average particle diameter of 10 μm or less allow a resin film containing the electroconductive particles to have sufficient mechanical characteristics as a resin film to be used for a TFT support substrate.

The average particle diameter can be measured from an electron micrograph taken with a scanning electron microscope (SEM) or a transmission electron microscope (TEM). Specifically, an ion milling device is used to expose the cross-section of a resin film, the cross-section is observed using an SEM, 50 particles observed in this manner are measured for the particle diameter, and the resulting arithmetic mean value is regarded as the average particle diameter. In this regard, this particle diameter is regarded as the Feret's diameter of the resin film in the film thickness direction. The Feret's diameter means the distance between the two parallel lines sandwiching a particle in a specified direction (a specified direction diameter).

The amount of the electroconductive particles in a resin film in the present invention is preferably 0.01 parts by mass or more, more preferably 0.05 parts by mass or more, still more preferably 0.1 parts by mass or more, with respect to 100 parts by mass of a heat-resistant resin in the resin film. In addition, the amount of the electroconductive particles is preferably 3 parts by mass or less, more preferably 1.5 parts by mass or less, still more preferably 1 part by mass or less, with respect to 100 parts by mass of the heat-resistant resin in the resin film. The electroconductive particles in an amount of 0.01 parts by mass or more make it possible to decrease the sheet resistance of a resin film. The electroconductive particles in an amount of 3 parts by mass or less allow a resin film containing this amount of electroconductive particles to have sufficient mechanical characteristics as a resin film to be used for a TFT support substrate.

(Ionic Compound)

In the present invention, the resin film may further contain an ionic compound as an additive in addition to a heat-resistant resin. Examples of ionic compounds that can be used include: metal complexes such as tris(2,4-pentanedionato)iron (III); organic salts such as ammonium acetate; and the like. The amount of these ionic compounds in a resin film is preferably 0.1 parts by mass or more, more preferably 0.5 parts by mass or more, with respect to 100 parts by mass of the heat-resistant resin in the resin film. In addition, the amount of these ionic compounds in a resin film is preferably 10 parts by mass or less, more preferably 5 parts by mass or less, still more preferably 3 parts by mass or less, with respect to 100 parts by mass of the heat-resistant resin in the resin film.

(Heat-Resistant Resin)

As above-mentioned, a resin film according to an embodiment of the present invention contains a heat-resistant resin. A heat-resistant resin in the present invention refers to a resin that does not have a melting point or a decomposition temperature at 300° C. or less. Examples of such heat-resistant resins include polyimide, polybenzoxazole, polybenzothiazole, polybenzimidazole, polyamide, polyethersulfone, polyether ether ketone, and the like. Among others, heat-resistant resins that can preferably be used for the present invention include polyimide and polybenzoxazole, of which polyimide is more preferable. In cases where the heat-resistant resin is polyimide, a resin film containing the heat-resistant resin and used in production of display substrates using the resin film can have: good heat resistance properties (including outgassing characteristics, glass transition temperature, and the like) against temperatures in the production processes; and good mechanical characteristics suitable to impart toughness to the produced displays.

A polyimide as the heat-resistant resin in the present invention is preferably a resin having a repeating unit represented by the chemical formula (1).

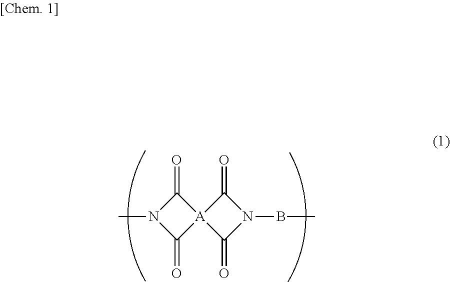

In the chemical formula (1), A represents a tetravalent tetracarboxylic acid residue having 2 or more carbon atoms. B represents a divalent diamine residue having 2 or more carbon atoms.

Specifically, A in the chemical formula (1) is preferably a tetravalent hydrocarbon group having 2 to 80 carbon atoms. In addition, A may be a tetravalent organic group having 2 to 80 carbon atoms and containing hydrogen and carbon as essential elements and one or more atoms selected from boron, oxygen, sulfur, nitrogen, phosphorus, silicon, and halogens. For each of boron, oxygen, sulfur, nitrogen, phosphorus, silicon, and a halogen, the number of atoms contained in A in the chemical formula (1) is preferably in the range of 20 or less, and the number of atoms contained in A in the chemical formula (1) is more preferably in the range of 10 or less.

Examples of tetracarboxylic acid that gives A in the chemical formula (1) include, but are not limited particularly to, known ones. Examples of tetracarboxylic acids include pyromellitic acid, 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenonetetracarboxylic acid, 2,2-bis(3,4-dicarboxyphenyl)hexafluoropropane, bis(3,4-dicarboxyphenyl)sulfone, bis(3,4-dicarboxyphenyl)ether, cyclobutanetetracarboxylic acid, 1,2,3,4-cyclopentanetetracarboxylic acid, 1,2,4,5-cyclohexanetetracarboxylic acid, tetracarboxylic acids described in WO2017/099183, and the like.

These tetracarboxylic acids can be used in their original form or in the form of acid anhydride, active ester, or active amide. In addition, tetracarboxylic acids that give A in the chemical formula (1) may be used in combination of two or more kinds thereof.

As below-mentioned, from the viewpoint of the mechanical strength of a resin film, it is preferable to use, as a tetracarboxylic acid that gives A in the chemical formula (1), 50 mol % or more of aromatic tetracarboxylic acid with respect to the total amount of tetracarboxylic acids. This A preferably contains, as a main component, a tetravalent tetracarboxylic acid residue represented by the chemical formula (2) or chemical formula (3), among others.

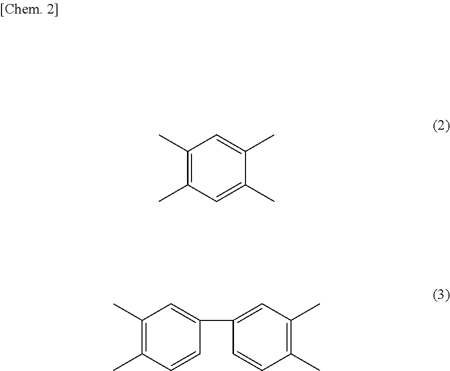

That is, it is preferable to use a pyromellitic acid or 3,3′,4,4′-biphenyltetracarboxylic acid as a main component of A. As used herein, a “main component” refers to a component that accounts for 50 mol % or more of the total amount of tetracarboxylic acids. More preferably, a main component of A is a component that accounts for 80 mol % or more of the total amount of tetracarboxylic acids. Polyimides obtained from these tetracarboxylic acids have a rigid structure, thus making it possible to obtain a resin film having excellent mechanical strength. In addition, a resin film containing electroconductive particles make it less likely that the electroconductive particles are agglomerated, making it possible to inhibit the addition of electroconductive particles from decreasing the mechanical strength.

As a tetracarboxylic acid that gives A in the chemical formula (1), a silicon-containing tetracarboxylic acid such as dimethylsilane diphthalic acid or 1,3-bis(phthalic acid)tetramethyl disiloxane may be used with a view to increasing the coatability that a resin composition for forming a resin film has to a support and increasing the resistance of the resin film to oxygen plasma used for cleaning and the like and to UV ozone processing. It is preferable that such a silicon-containing tetracarboxylic acid accounts for 1 to 30 mol % of the total amount of tetracarboxylic acids.

For the tetracarboxylic acids given above as examples for A in the chemical formula (1), a part of the hydrogen atoms contained in a tetracarboxylic acid residue may be each substituted with a hydrocarbon group having 1 to 10 carbon atoms such as a methyl group or ethyl group; a fluoroalkyl group having 1 to 10 carbon atoms such as a trifluoromethyl group; or another group such as F, Cl, Br, or I. In addition, the tetracarboxylic acid residue in which a part of the hydrogen atoms are each substituted with an acidic group such as OH, COOH, SO₃H, CONH₂, or SO₂NH₂ enhances the solubility of the heat-resistant resin or precursor thereof in an aqueous alkali solution, and thus, is preferably used for the below-mentioned photosensitive resin composition.

In the chemical formula (1), B is preferably a divalent hydrocarbon group having 2 to 80 carbon atoms. In addition, B may be a divalent organic group having 2 to 80 carbon atoms and including hydrogen and carbon as essential elements and one or more atoms selected from boron, oxygen, sulfur, nitrogen, phosphorus, silicon, and halogens. For each of boron, oxygen, sulfur, nitrogen, phosphorus, silicon, and a halogen, the number of atoms contained in B in the chemical formula (1) is preferably in the range of 20 or less, and the number of atoms contained in B in the chemical formula (1) is more preferably in the range of 10 or less.

Examples of usable diamines that give B in the chemical formula (1) include, but are not limited particularly to, known ones. Examples of such diamines include, m-phenylene diamine, p-phenylene diamine, 4,4′-diaminobenzanilide, 3,4′-diaminodiphenylether, 4,4′-diaminodiphenylether, 2,2′-dimethyl-4,4′-diaminobiphenyl, 2,2′-di(trifluoromethyl)-4,4′-diaminobiphenyl, bis(4-aminophenoxyphenyl)sulfone, 1,4-bis(4-aminophenoxy)benzene, 1,3-bis(3-aminophenoxy)benzene, 1,3-bis(4-aminophenoxy)benzene, bis(3-amino-4-hydroxyphenyl)hexafluoropropane, ethylenediamine, propylenediamine, butanediamine, 1,3-bis(3-aminopropyl)tetramethyl disiloxane, cyclohexanediamine, 4,4′-methylenebis(cyclohexylamine), diamines described in WO2017/099183, and the like.

These diamines may be used in their original form or in the form of corresponding trimethylsilylated diamines. In addition, diamines that give B in the chemical formula (1) may be used in combination of two or more kinds thereof.

As below-mentioned, from the viewpoint of the mechanical strength of a resin film, it is preferable to use, as a diamine that gives B in the chemical formula (1), 50 mol % or more of aromatic diamine compound with respect to the total amount of diamine compounds. This B preferably contains, as a main component, a divalent diamine residue represented by the chemical formula (4) among others.

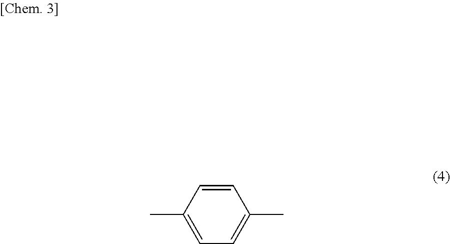

That is, it is preferable to use p-phenylene diamine as a main component of B. As used herein, a “main component” refers to a component that accounts for 50 mol % or more of the total amount of diamine compounds. More preferably, a main component of B is a component that accounts for 80 mol % or more of the total amount of diamine compounds. Polyimides obtained using p-phenylene diamine (that is, polyimides containing a p-phenylene diamine residue) have a rigid structure, thus making it possible to obtain a resin film having excellent mechanical strength. In addition, a resin film containing electroconductive particles make it less likely that the electroconductive particles are agglomerated, making it possible to inhibit the addition of electroconductive particles from decreasing the mechanical strength.

It is particularly preferable that A in the chemical formula (1) contains, as a main component, a tetravalent tetracarboxylic acid residue represented by the chemical formula (2) or the chemical formula (3), and that B contains, as a main component, a divalent diamine residue represented by the chemical formula (4). Polyimides having such a structure have a more rigid structure, thus making it possible to obtain a resin film having excellent mechanical strength. In addition, a resin film containing electroconductive particles make it less likely that the electroconductive particles are agglomerated, making it possible to further inhibit the addition of electroconductive particles from decreasing the mechanical strength.

As a diamine that gives B in the chemical formula (1), a silicon-containing diamine such as 1,3-bis(3-aminopropyl)tetramethyl disiloxane or 1,3-bis(4-anilino)tetramethyl disiloxane may be used with a view to increasing the coatability that a resin composition for forming a resin film has to a support and increasing the resistance of the resin film to oxygen plasma used for cleaning and the like and to UV ozone processing. It is preferable that such a silicon-containing diamine compound accounts for 1 to 30 mol % of the total amount of diamine compounds.

For the diamine compounds given above as examples for B in the chemical formula (1), one or more of the hydrogen atoms contained in a diamine compound may be substituted with a hydrocarbon group having 1 to 10 carbon atoms such as a methyl group or ethyl group; a fluoroalkyl group having 1 to 10 carbon atoms such as a trifluoromethyl group; or another group such as F, Cl, Br, or I. In addition, the diamine compound in which one or more of the hydrogen atoms are each substituted with an acidic group such as OH, COOH, SO₃H, CONH₂, or SO₂NH₂ enhances the solubility of the heat-resistant resin or precursor thereof in an aqueous alkali solution, and thus, is preferably used for the below-mentioned photosensitive resin composition.

(Method of Producing Resin Composition)

A resin film according to an embodiment of the present invention can be obtained by: coating a support with a resin composition containing a heat-resistant resin or a precursor thereof and a solvent; and firing the resulting product. A precursor of heat-resistant resin is a resin that can be converted into a heat-resistant resin as described above by heat treatment, chemical treatment, or the like. Examples of such a heat-resistant resin precursor to be preferably used for the present invention are polyimide precursors and polybenzoxazole precursors. More specifically, such a precursor of a heat-resistant resin is a polyamic acid or a polyhydroxyamide, more preferably a polyamic acid. In this regard, this polyamic acid is preferably a resin having a repeating unit represented by the chemical formula (5).

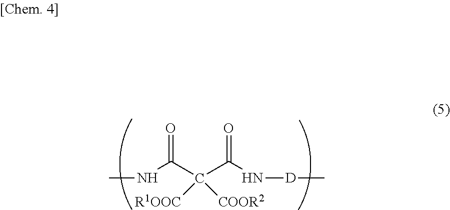

In the chemical formula (5), C represents a tetravalent tetracarboxylic acid residue having 2 or more carbon atoms. D represents a divalent diamine residue having 2 or more carbon atoms. In the chemical formula (5), R¹ and R² each represent a hydrogen atom, alkali metal ion, ammonium ion, imidazolium ion, hydrocarbon group containing 1 to 10 carbon atoms, or alkyl silyl group containing 1 to 10 carbon atoms. Specific examples of C in the chemical formula (5) include the above-mentioned structures described as specific examples of A in the chemical formula (1). Specific examples of D in the chemical formula (5) include the above-mentioned structures described as specific examples of B in the chemical formula (1).

As the above-mentioned solvent contained in a resin composition, any solvent that dissolves a heat-resistant resin or a precursor thereof can be used, without particular limitation. Examples of solvents include: aprotic polar solvents such as N-methyl-2-pyrrolidone, γ-butyrolactone, N,N-dimethylformamide, N,N-dimethylacetamide, 3-methoxy-N,N-dimethylpropioneamide, 3-butoxy-N,N-dimethylpropioneamide, N,N-dimethylisobutylamide, 1,3-dimethyl-2-imidazolidinone, N,N′-dimethylpropyleneurea, and dimethylsulfoxide; ethers such as tetrahydrofuran, dioxane, propylene glycol monomethyl ether, propylene glycol monoethyl ether, diethylene glycol monomethyl ether, diethylene glycol monoethyl ether diethylene glycol ethylmethyl ether, and diethylene glycol dimethyl ether; ketones such as acetone, methylethyl ketone, diisobutyl ketone, diacetone alcohol, and cyclohexanone; esters such as ethyl acetate, propylene glycol monomethyl ether acetate, ethyl lactate, 3-methyl-3-methoxybutyl acetate, ethylene glycol ethyl ether acetate, and 3-methoxybutyl acetate; and aromatic hydrocarbons such as toluene and xylene; solvents described in WO2017/099183; and the like. Any one of these solvents can be used singly, or two or more thereof can be used.

A heat-resistant resin or a precursor thereof can be polymerized by a known method. For example, in cases where the heat-resistant resin is a polyimide, a polyamic acid, which is a precursor of a heat-resistant resin, can be produced by polymerizing an acid component, such as a tetracarboxylic acid or the corresponding acid dianhydride, active ester, or active amide, with a diamine component, such as a diamine or the corresponding trimethylsilylated diamine, in a reaction solvent. In addition, the carboxyl group in this polyamic acid may be in a salified state with an alkali metal ion, ammonium ion, or imidazolium ion or in an esterified state with a hydrocarbon group having 1 to 10 carbon atoms or an alkylsilyl group having 1 to 10 carbon atoms. In cases where the heat-resistant resin is a polybenzoxazole, polyhydroxyamide, which is a precursor of a heat-resistant resin, can be produced through a condensation reaction between a bisaminophenol compound and dicarboxylic acid. Specific examples of methods of obtaining such a precursor of a heat-resistant resin include a method in which an acid is allowed to react with a dehydration condensation agent such as dicyclohexyl carbodiimide (DCC), followed by adding a bisaminophenol compound to the reaction product, and a method in which a tertiary amine such as pyridine is added to a bisaminophenol compound, followed by adding a dicarboxylic dichloride solution to the resulting solution dropwise. In producing a resin having a capped end, such a resin of interest can be produced by allowing an end capping agent to react with a monomer before polymerization or to react with a resin during polymerization and after polymerization.

Examples of the above-described reaction solvents include the solvents described as specific examples of a solvent contained in the resin composition, wherein the solvents can each be used singly or be used in combination of two or more kinds thereof. It is preferable that the amount of the above-described reaction solvent to be used is adjusted so that the tetracarboxylic acid and diamine compound altogether can account for 0.1 to 50 mass % of the total amount of the reaction solution.

In addition, the reaction temperature is preferably −20° C. to 150° C., more preferably 0 to 100° C. Furthermore, the reaction time is preferably 0.1 to 24 hours, more preferably 0.5 to 12 hours.

In addition, it is more preferable that the diamine compound and tetracarboxylic acid that are used in the reaction are closer in the number of moles. The closer in the number of moles they are, the more easily a resin film having excellent mechanical characteristics can be obtained. In addition, an amine group as an end of a heat-resistant resin allows the dispersibility of electroconductive particles to be enhanced, compared with a group other than an amine group. Because of this, the number of moles of the diamine compound is preferably larger than the number of moles of the tetracarboxylic acid from the viewpoint of the dispersibility of the electroconductive particles. Specifically, the above-mentioned reaction solvent preferably contains 99.5 to 95 mol, more preferably 99.5 to 97 mol, of tetracarboxylic dianhydride with respect to 100 mol of diamine.

The resulting polyamic acid solution may be used directly as a resin composition. In this case, a resin composition of interest can be obtained without isolating the resin if the same solvent as intended for the resin composition is used as the reaction solvent, or the solvent is added after the completion of the reaction.

Part of the repeating units of the resulting polyamic acid may further be imidized or esterified. In this case, the polyamic acid solution resulting from polymerization of a polyamic acid may be used directly in a reaction, or the polyamic acid that is isolated may be used for a reaction.

In addition, to obtain a resin film containing electroconductive particles, the above-mentioned electroconductive particles are preferably dispersed in the resin composition.

Examples of methods of dispersing electroconductive particles in a resin composition include a method in which electroconductive particles are mixed in a resin composition and then dispersed therein, and a method in which electroconductive particles are mixed in a solvent and then preliminarily dispersed therein, followed by mixing the resulting resin composition. In cases where a plurality of types of electroconductive particles are contained in the resin composition, it is preferable that electroconductive particles of each type are dispersed in a solvent suitable to disperse those of the type or in a resin composition containing the solvent, followed by mixing the materials. In any case, electroconductive particles may further be dispersed after the resin composition and electroconductive particles are mixed, or a dispersant may be mixed in the resin composition when electroconductive particles are dispersed. Electroconductive particles can be dispersed by a known method using a disperser such as a triple roll, sand grinder, ball mill, bead mill, or the like. The dispersion intensity, dispersion time, and the like of electroconductive particles in the resin composition are preferably adjusted as appropriate.

Examples of solvents to be used for the dispersion of electroconductive particles include the solvents described as specific examples of a solvent contained in the resin composition, wherein the solvents can each be used singly or be used in combination of two or more kinds thereof. In particular, to enhance the dispersion effect of carbon particles as an example of electroconductive particles, a solvent containing at least an amide-based polar solvent is preferably used. It is more preferable to use a solvent the main component of which is an amide-based polar solvent or a solvent composed of an amide-based polar solvent alone. As used herein, a “main component” refers to a component the amount of which is more than (1/n)×100 wt % in a solvent mixture composed of n types of solvents. For example, in cases where a solvent the main component of which is an amide-based polar solvent is a two-component solvent, this amide-based polar solvent is contained in an amount of more than 50 wt % in the two-component solvent. In cases where a solvent the main component of which is an amide-based polar solvent is a three-component solvent, this amide-based polar solvent is contained in an amount of more than 33 wt % in the three-component solvent. In addition, to decrease the heat generation of electroconductive particles during dispersion and inhibit the gelation of a solvent, an ethylene glycol-based or propylene glycol-based ether acetate solvent having a surface tension of 26 to 33 dyne/cm may be added. In this case, the ether acetate solvent is preferably mixed in an amount of 1 to 25 wt %, more preferably mixed in an amount of 5 to 20 wt %, with respect to the whole solvent mixture.

In addition, the resin composition may contain, if necessary, at least one additive selected from the following: photoacid generating agents (a), thermal crosslinking agents (b), thermal acid generating agents (c), compounds containing a phenolic hydroxy group (d), adhesion improving agents (e), and surface active agents (f). Specific examples of these additives include those described in WO2017/099183.

(Photoacid Generating Agent (a))

By containing a photoacid generating agent (a), the above-mentioned resin composition can be formed into a photosensitive resin composition. Containing such a photoacid generating agent (a) allows acid to be generated in light-irradiated portions of the resin composition so that these light-irradiated portions can increase in solubility in aqueous alkali solutions, resulting in a positive type relief pattern in which the light-irradiated portions are dissolvable. Containing the photoacid generating agent (a) and an epoxy compound or such a thermal crosslinking agent (b) as described later allows the acid generated in the light-irradiated portions to promote the crosslinking reaction of the epoxy compound or thermal crosslinking agent (b), resulting in a negative type relief pattern in which the light-irradiated portions are insolubilized.

Examples of such photoacid generating agents (a) include quinone diazide compounds, sulfonium salts, phosphonium salts, diazonium salts, and iodonium salts. The resin composition may contain two or more of these agents, and thus, enables a photosensitive resin composition having high sensitivity to be obtained.

(Thermal Crosslinking Agent (b))

The resin composition containing the thermal crosslinking agent (b) makes it possible to enhance the chemical resistance and hardness of a resin film obtained by heating the composition. The amount of the thermal crosslinking agent (b) is preferably 10 parts by mass or more and 100 parts by mass or less with respect to 100 parts by mass of the resin composition. The thermal crosslinking agent (b) in an amount of 10 parts by mass or more and 100 parts by mass or less allows the resulting resin film to have high strength and allows the resin composition to have excellent storage stability.

(Thermal Acid Generating Agent (c))

The above-described resin composition may further contain a thermal acid generating agent (c). The thermal acid generating agent (c) generates an acid when heated after development as described below to promote the crosslinking reaction between the heat-resistant resin or a precursor thereof and the thermal crosslinking agent (b) and also promote the curing reaction. This makes it possible that the chemical resistance of the resulting heat-resistant resin film (resin film containing a heat-resistant resin) is enhanced, and that the film loss is reduced. The acid generated by the thermal acid generating agent (c) is preferably a strong acid, which is preferably an aryl sulfonic acid such as p-toluene sulfonic acid or benzene sulfonic acid, or an alkyl sulfonic acid such as methane sulfonic acid, ethane sulfonic acid, or butane sulfonic acid. The amount of the thermal acid generating agent (c) is preferably 0.5 parts by mass or more, preferably 10 parts by mass or less, with respect to 100 parts by mass of the resin composition, from the viewpoint of promoting the crosslinking reaction.

(Compound Containing Phenolic Hydroxy Group (d))

The resin composition may contain a compound having a phenolic hydroxy group (d), if necessary, with a view to helping the alkaline development of the photosensitive resin composition. If such a compound having a phenolic hydroxy group (d) is contained, the resulting photosensitive resin composition will be scarcely dissolved in an alkaline developer before light exposure, but will be easily dissolved in an alkaline developer after light exposure, leading to a decreased film loss during development and ensuring rapid and easy development. Accordingly, the sensitivity can be enhanced easily. The amount of such a compound having a phenolic hydroxy group (d) is preferably 3 parts by mass or more and 40 parts by mass or less with respect to 100 parts by mass of the resin composition.

(Adhesion Improving Agent (e))

The above-described resin composition may contain an adhesion improving agent (e). Containing such an adhesion improving agent (e) makes it possible that a photosensitive resin film used for development has higher adhesion to an underlying base material such as a silicon wafer, ITO, SiO₂, or silicon nitride. In addition, the higher adhesion between a heat-resistant resin film and an underlying base material can enhance resistance to oxygen plasma used for cleaning and the like and to UV ozone processing. In addition, such higher adhesion can prevent a film lifting phenomenon in which a resin film is lifted from a substrate in vacuum processes during firing or during display production. The amount of the adhesion improving agent (e) is preferably 0.005 to 10 mass % with respect to 100 mass % of the resin composition.

(Surface Active Agent (f))

The resin composition may contain a surface active agent (f) in order to enhance the coatability. Examples of surface active agents (f) include fluorochemical surface active agents such as “Fluorad” (registered trademark) manufactured by Sumitomo 3M, “Megafac” (registered trademark) manufactured by DIC Corporation, “Surflon” (registered trademark) manufactured by Asahi Glass Co., Ltd.; organic siloxane surface active agents such as KP341 manufactured by Shin-Etsu Chemical Co., Ltd., DBE manufactured by Chisso Corporation, “Polyflow” (registered trademark) and “Glanol” (registered trademark) manufactured by Kyoeisha Chemical Co., Ltd., and BYK manufactured by BYK-Chemie; and acrylic polymer surface active agents such as Polyflow manufactured by Kyoeisha Chemical Co., Ltd. The amount of such a surface active agent (f) is preferably 0.01 to 10 parts by mass with respect to 100 parts by mass of the resin composition.

Examples of methods of dissolving an additive such as the above-mentioned photoacid generating agent (a), thermal crosslinking agent (b), thermal acid generating agent (c), compound containing a phenolic hydroxy group (d), adhesion improving agent (e), or surface active agent (f) in a resin composition include stirring and heating. In cases where a photoacid generating agent (a) is contained, it is preferable that an appropriate heating temperature is adopted in the range, commonly from room temperature to 80° C., where a photosensitive resin composition with unimpaired performance is obtained. There are no specific limitations on the order of dissolving these components, and for example, the compound with the lowest solubility may be dissolved first followed by the others in the order of solubility. Further, the dissolution of those components, such as the surface active agent (f), that are likely to form bubbles when dissolved by stirring may be preceded by the dissolution of the other components so that the dissolution of the latter will not be hindered by bubble formation.

A varnish as an example of a resin composition obtained by the above-mentioned production methods is preferably filtrated through a filter to remove foreign substances such as dusts. Filters with a pore size of, for example, 10 μm, 3 μm, 1 μm, 0.5 μm, 0.2 μm, 0.1 μm, 0.07 μm, or 0.05 μm are available, though there are no specific limitations on the size. The filter to be used for the filtration may be of such a material as polypropylene (PP), polyethylene (PE), nylon (NY), or polytetrafluoroethylene (PTFE), of which polyethylene and nylon are preferable.

<Method of Producing Resin Film>

Next, a method of producing a resin film according to an embodiment of the present invention will be described. This method of producing a resin film is an example of a method of producing a resin film according to an embodiment of the present invention from the above-mentioned resin composition. Specifically, this method of producing a resin film includes: a coating step of coating a support with a resin composition containing a heat-resistant resin or a precursor of the heat-resistant resin and a solvent; and a heating step of heating a coating film obtained by the coating step, to obtain a resin film.

In the coating step, a varnish, which is one of the resin compositions in the present invention, is first applied onto a support. Examples of supports include wafer substrates such as silicon, gallium arsenide, and the like; glass substrates such as sapphire glass, soda lime glass, alkali-free glass, and the like; metal substrates or metal foils such as stainless steel, copper, and the like; ceramics substrates; and the like. Among others, alkali-free glass is preferable from the viewpoint of surface smoothness and dimensional stability against heating.

Examples of varnish coating methods include spin coating, slit coating, dip coating, spray coating, and printing, which may be used in combination. In cases where a resin film is used as a substrate for displays (for example, a support substrate of a TFT provided in a display), it is necessary to apply a varnish onto a support having a large size, and accordingly, a slit coating method in particular is preferably used.

The support may be pretreated in advance before being coated. Examples of such pretreatment methods include a method in which a pretreatment agent is dissolved in an amount of 0.5 to 20 mass % in a solvent such as isopropanol, ethanol, methanol, water, tetrahydrofuran, propylene glycol monomethyl ether acetate, propylene glycol monomethyl ether, ethyl lactate, or diethyl adipate to prepare a solution, which is then used to treat the surface of a support by a technique such as spin coating, slit die coating, bar coating, dip coating, spray coating, or steam processing. In addition, vacuum drying may be carried out, if necessary, followed by heat treatment at 50° C. to 300° C. to accelerate the reaction between the support and the pretreatment agent.

The coating step is commonly followed by drying the varnish coating film. Useful drying methods include reduced pressure drying methods, thermal drying methods, and combinations thereof. The reduced pressure drying methods include, for example, a process in which a support with a coating film formed thereon is put in a vacuum chamber, followed by reducing the pressure in the vacuum chamber. Thermal drying may be performed by using a tool such as hot plate, oven, and infrared ray. When a hot plate is used, the support having the coating film formed thereon is put directly on the plate or held on jigs such as proxy pins fixed on the plate, followed by thermal drying. The heating temperature varies depending on the type and purpose of the solvent used for the varnish, and the heating is performed preferably at a temperature in the range of from room temperature to 180° C. for one minute to several hours.

In cases where a resin composition to be applied contains a photoacid generating agent, a pattern can be formed by processing the dried coating film by the method described below. In this method, for example, an actinic ray is radiated to the coating film through a mask of a desired pattern to perform light exposure. Different types of actinic ray available for the light exposure include ultraviolet ray, visible light, electron beam, and X-ray, and the i-line (365 nm), h-line (405 nm), and g-line (436 nm) of mercury lamps are preferred for the present invention. If the film is positively photosensitive, the exposed parts are dissolved by a developer. If the film is negatively photosensitive, the exposed parts harden and become insoluble in a developer.

After the exposure step, a developer is used to remove the exposed parts of a positive film or unexposed parts of a negative film to form a desired pattern on the coating film. For either of a positive film and a negative film, a preferable developer is an aqueous solution of a compound that exhibits alkalinity, such as tetramethyl ammonium. To such an aqueous alkali solution, a polar solvent such as N-methyl-2-pyrrolidone, alcohols, esters, ketones, or the like may optionally be added singly or in combination of two or more kinds thereof.

Then, a heating step is carried out, in which the coating film on the support is heat-treated to produce a resin film. In this heating step, the coating film is heat-treated in the range of 180° C. or more and 600° C. or less, preferably 220° C. or more and 600° C. or less, to fire the coating film. The resin film can thus be produced on the support. The heating temperature of 220° C. or more allows the imidization to progress sufficiently and affords a resin film having excellent mechanical characteristics.

(Arithmetic Mean Roughness)

In cases where a resin film according to an embodiment of the present invention contains electroconductive particles, the arithmetic mean roughness of the resin film face tends to increase. For this reason, the arithmetic mean roughness of the resin film face is preferably improved by the below-mentioned first to third methods.

The first method is a method in which a resin film fired by heating is polished. In the first method, abrasive grains used for polishing may be either fixed abrasive grains or loose abrasive grains. The resin film may be polished by either a dry polishing method or a wet polishing method, and specifically, a chemical-mechanical polishing (hereinafter referred to as CMP) method is preferable. CMP is a technique in which the surface of a work piece is mechanically polished with abrasive grains contained in a polishing liquid and with a polishing pad while the surface is chemically altered with the polishing liquid so as to be easily polished. For example, in polishing a silicon wafer, a slurry solution formed by mixing loose abrasive grains and an acid or alkaline solution is supplied to a polishing pad to polish the surface of the silicon wafer. This slurry solution has, added thereto, an oxidizing agent such as hydrogen peroxide or ammonium persulfate, and, for a metal wiring wafer, additionally has an organic complexing agent for stabilizing the metal ion, a corrosion inhibitor for inhibiting transient etching, a surface active agent for decreasing the surface tension of a solution, or the like in suitable amounts. The present invention is not limited to the above-mentioned examples, and it is preferable that a polishing liquid containing a component that chemically acts on electroconductive particles to be added is selected for use. In cases where the first method such as this is applied to a method of producing a resin film, this method of producing a resin film includes a polishing step of polishing a resin film heated by above-mentioned heating step.

The second method is a method in which a resin film fired by heating is irradiated with a laser. In general, irradiating a solid with a laser beam causes the surface of the solid to be decomposed by laser ablation. In cases where a resin film containing electroconductive particles is irradiated with a laser beam, each of the resin film and electroconductive particles undergoes laser ablation. Except for some exceptions, electroconductive particles have a large charge density and a small band gap, and thus, have a tendency to have a larger absorbance than a resin film. Accordingly, the electroconductive particles absorb a laser beam more easily, and thus, tend more to undergo decomposition caused by laser irradiation than a resin film does. In addition, a resin film containing electroconductive particles has the electroconductive particles exposed as protruding portions on the resin film face. Accordingly, allowing the electroconductive particles to be decomposed efficiently by laser irradiation makes it possible to improve the arithmetic mean roughness of the resin film face. In the second method, a laser beam that can be used is a laser beam in the wavelength range of from ultraviolet light to infrared light. In cases where the second method such as this is applied to a method of producing a resin film, this method of producing a resin film includes an irradiating step of irradiating, with a laser, a resin film heated by above-mentioned heating step.

The third method is a method in which resist is applied onto a resin film fired by heating, and the resist-coated side of the obtained laminate is dry-etched to expose the resin film. Specifically, a resist coating step is first carried out in this third method. In this resist coating step, a resin film heated by the above-mentioned heating step (specifically, fired by heating) is coated with resist to thereby form a laminate of a resin film on a support and a resist covering the resin film. Such a resist may be any photosensitive or non-photosensitive material, and for example, a novolac-based resist, polyhydroxystyrene-based resist, acryl-based resist, or the like can be used. From the viewpoint of improving the arithmetic mean roughness achieved after etching, the etching resistance of the electroconductive particles and that of the resist are preferably closer to each other. For example, in cases where the electroconductive particles are carbon particles, a resist to be used is preferably a material having many aromatic rings, such as novolac.

In this third method, the resist coating step is followed by an etching step. In this etching step, the resist-coated side of the laminate obtained in the resist coating step is dry-etched to expose the resin film. In this case, examples of dry-etching treatments that can be used include plasma etching, reactive ion etching, and the like. In addition, examples of etching gases that can be used include oxygen, argon, carbon tetrafluoride, and the like, and oxygen is preferably used to etch resist and electroconductive particles efficiently. In cases where the third method such as above-mentioned is applied to a method of producing a resin film, this method of producing a resin film includes the above-mentioned resist coating step and etching step.

In this regard, the resist preferably has a film thickness of 0.5 μm or more and 5 μm or less, more preferably 1 μm or more and 3 μm or less. The resist which is 0.5 μm or more allows the arithmetic mean roughness after the resist coating to be good, and also allows the arithmetic mean roughness of the resin film exposed by the subsequent etching treatment to be favorable. The resist which is 5 μm or less makes it possible to shorten the etching time.

The recipes of the above-mentioned first to third methods are preferably applied to a predetermined resin film face of a resin film, that is, a resin film face having a sheet resistance of more than 1×10¹²Ω and less than 1×10¹⁶Ω.

The arithmetic mean roughness of that resin film face of a resin film in the present invention which has a sheet resistance of more than 1×10¹²Ω and less than 1×10¹⁶Ω is not limited to any particular value, and is preferably 10 nm or less, more preferably 9 nm or less. The resin film face having an arithmetic mean roughness of 10 nm or less does not lead to generating cracks in an inorganic film during TFT formation or causing a variation in film thickness, thus making it possible to inhibit a performance variation among TFT elements. In cases where a resin film contains electroconductive particles, that face of the resin film which has an arithmetic mean roughness of 10 nm or less makes it possible to inhibit damage from being caused to a TFT in a flexible device which has been bent, wherein the damage is presumably caused by the stress concentration on the inorganic film on the electroconductive particles exposed on the film face.

In this regard, the arithmetic mean roughness in the present invention is an arithmetic mean roughness Ra determined in accordance with the Japanese Industrial Standards (JIS B 0633:2001) using a surface texture measuring instrument (SURFCOM 1400D, manufactured by Tokyo Seimitsu Co., Ltd.). In the measurement conditions for this arithmetic mean roughness, an evaluation length of 1.25 mm and a cutoff wavelength of 0.25 mm are used.

The resin film obtained through the above-mentioned coating step and heating step can be used after being detached from the support, or can be directly used without being detached from the support.

Examples of detaching methods include: a method in which the resin film is mechanically detached; a method in which the resin film is immersed in water; a method in which the resin film is immersed in a liquid chemical such as hydrochloric acid or hydrofluoric acid; and a method in which a laser beam in the wavelength range from ultraviolet light to infrared light is radiated to the interface between the resin film and the support. In particular, in cases where a device is produced on a resin film (for example, a polyimide resin film) followed by detaching the resulting product, it is necessary to detach the product without damaging the device, and thus, the product is preferably detached using an ultraviolet laser. To facilitate the detachment, the support may be coated with a release agent or filmed with a sacrifice layer before the support is coated with a resin composition such as a varnish. Examples of release agents include silicone-based, fluorine-based, aromatic polymer-based, and alkoxysilane-based release agents, and the like. Examples of sacrifice layers include metal films, metal oxide films, amorphous silicon films, and the like.

The film thickness of a resin film according to an embodiment of the present invention is not limited to any particular value, and is preferably 4 μm or more, more preferably 5 μm or more, still more preferably 6 μm or more. In addition, the film thickness of the resin film is preferably 40 μm or less, more preferably 30 μm or less, still more preferably 25 μm or less. The resin film having a film thickness of 4 μm or more affords mechanical characteristics sufficient for resin films for TFT support substrates. In addition, the resin film having a film thickness of 40 μm or less affords toughness sufficient for resin films for TFT support substrates.

If foreign substances are on a resin film for a TFT support substrate, gas emitted from the foreign substances destroy the TFT element in high-temperature processes in TFT production processes, and this destruction of the TFT element causes a pixel defect on the display. Accordingly, the number of foreign substances on the resin film is preferably as small as possible. For example, the number of foreign substances 10 μm or more in size is preferably 50 or less, more preferably 20 or less, still more preferably 10 or less, on the region of a substrate 350 mm in length×300 mm in width. In this regard, the number of foreign substances on a resin film can be measured using, for example, an automatic optical testing device such as an automatic defective charge coupled device (CCD) testing device.

<Display and Method of Producing the Same>

Next, a display and a method of producing the same according to an embodiment of the present invention will be described. A display according to an embodiment of the present invention includes the above-mentioned resin film used as a support substrate of a TFT.

Below, a method of producing a display including a resin film according to an embodiment of the present invention will be described. This method of producing a display includes: a film-producing step of producing a resin film on a support by the above-mentioned method of producing a resin film; an element-forming step of forming a TFT element on this resin film; and a detaching step of detaching, from the support, the resin film having the TFT element formed thereon (in other words, the resin film for the TFT support substrate).

First, in the film-producing step, the coating step, the heating step, and the like are carried out in accordance with the above-mentioned method of producing a resin film, to produce the resin film on a support such as a glass substrate. The resin film thus produced can be used as a support substrate of a TFT element (hereinafter, suitably referred to as a TFT support substrate), whether the resin film is formed on a support or detached from a support. In addition, an inorganic film is provided on the resin film, if necessary. This makes it possible to prevent moisture, oxygen, or the like existing outside the substrate from passing through the resin film to degrade the pixel driving element, light-emitting element, or the like. Examples of inorganic films include silicon oxide (SiOx), silicon nitride (SiNy), silicon oxynitride (SiOxNy), and the like. Each of these may be used so as to form a monolayer, or two or more kinds of them may be laminated and used so as to form a multilayer. Such inorganic film layers may be, for example, stacked alternately with film layers of organic material such as polyvinyl alcohol. Such a method of forming an inorganic film is preferably carried out using a vapor deposition method such as the chemical vapor deposition (CVD) technique or the physical vapor deposition (PVD) technique. In addition, a TFT support substrate including a plurality of inorganic film layers or resin film layers can be produced by forming a resin film or another inorganic film on the inorganic film, if necessary. In terms of simplification of processes, the resin compositions to be used to produce the resin films are preferably the same.

In the element-forming step, a TFT element is subsequently formed on the resin film obtained as above-mentioned. In the present invention, the structure of the TFT element may be either a top gate type TFT or a bottom gate type TFT. In cases where the TFT element is a top gate type TFT, for example, a semiconductor layer, a gate insulation film, and a gate electrode are formed on a resin film, and then an interlayer insulation film is formed so as to cover them. Subsequently, contact holes are formed in this interlayer insulation film, and a pair of a source electrode and a drain electrode are formed so as to fill the contact holes. Further, an interlayer insulation film is formed so as to cover them.

The semiconductor layer contains a channel region (active layer) in the region opposing to the gate electrode. The semiconductor layer may be composed of a low-temperature polysilicon (LTPS), an amorphous silicon (a-Si), or the like, or may be composed of an oxide semiconductor such as indium tin zinc oxide (ITZO), indium gallium zinc oxide (IGZO:InGaZnO), zinc oxide (ZnO), indium zinc oxide (IZO), indium gallium oxide (IGO), indium tin oxide (ITO), or indium oxide (InO). In cases where these semiconductor layers are formed, a structure such as the above-mentioned resin film generally passes through high-temperature processes. For example, in the formation of an LTPS, an a-Si is formed and then can be annealed, for example, at 450° C. for 120 minutes for the purpose of dehydrogenation. In such high-temperature processes, the above-mentioned gas generation from foreign substances causes the inorganic film on the resin film to suffer film lifting, and, for example, destroys the semiconductor layer, resulting in damaging the TFT in some cases.

The gate insulation film is preferably formed of, for example, a monolayer film composed of one of silicon oxide (SiOx), silicon nitride (SiNx), silicon oxynitride (SiON), aluminium oxide (AlOx), and the like, or formed of a laminated film composed of two or more kinds thereof.

A gate electrode controls the carrier density of a semiconductor layer using applied gate voltage, and at the same time, functions as wiring for supplying an electrical potential. Examples of constituent materials of this gate electrode include a single kind of material or an alloy containing at least one of titanium (Ti), tungsten (W), tantalum (Ta), aluminium (Al), molybdenum (Mo), silver (Ag), neodymium (Nd), and copper (Cu). The constituent material of the gate electrode may be a compound containing at least one thereof or a laminated film containing two or more thereof. In addition, a constituent material to be used for this gate electrode may be, for example, a transparent conductive film of ITO or the like.

The interlayer insulation film is formed of, for example, an organic material such as an acryl-based resin, polyimide (PI), or novolac-based resin. Alternatively, the interlayer insulation film may be formed of an inorganic material such as a silicon oxide film, silicon nitride film, silicon oxynitride film, or aluminium oxide.

A source electrode and a drain electrode function as a source and a drain respectively in a TFT. The source electrode and the drain electrode include, for example, the same metal or transparent conductive film as among the materials listed above as the constituent materials of the gate electrode. For these source electrode and drain electrode, materials having good electrical conductivity are desirably selected.

The obtained TFT can be used for displays such as organic EL displays, liquid crystal displays, and electronic paper. In cases where a TFT is used for an organic EL display, a first electrode, organic EL element, second electrode, and sealing film are further formed in this order on the TFT. For example, the first electrode is connected to the above-mentioned source electrode and drain electrode, and the second electrode has a structure, for example, such that a cathode electrical potential common to the pixels is supplied to the second electrode through wiring or the like. The sealing film is a layer for protecting the organic EL element from the outside. This sealing film may be formed of, for example, an inorganic material such as silicon oxide (SiOx), silicon nitride (SiNx), or silicon oxynitride (SiON), or another organic material.

Finally in the detaching step, the resin film having a TFT element formed as above-mentioned is detached from the support, and a display including the resin film is thus produced. Examples of methods of detaching the resin film from the support along the interface therebetween include a method in which a laser is used, a method in which both are mechanically detached, or a method in which the support is etched. In the method in which a laser is used, the laser beam is applied to that side of a support such as a glass substrate which has no TFT element formed thereon, and thus, the resin film can be detached from the support without causing damage to the TFT element. Furthermore, to facilitate the detachment of the resin film from the support, a primer layer may be provided between the support and the resin film. A laser beam that can be used is a laser beam in the wavelength range of from ultraviolet light to infrared light, and is particularly preferably ultraviolet light. A more preferable laser beam is an excimer laser at 308 nm. Detachment energy for the detachment of the resin film from the support is preferably 250 mJ/cm² or less, more preferably 200 mJ/cm² or less.

### EXAMPLES

The present invention will be described below with reference to Examples and the like, but the present invention is not limited by the Examples and the like. First, the evaluation, measurement, testing, and the like carried out in the following Examples and Comparative Examples will be described.

(First Item: Evaluation of Number of Foreign Substances)

As the first item, evaluation of the number of foreign substances will be described. In this evaluation of the number of foreign substances, a laminate composed of a resin film obtained in each Example and a glass substrate was measured for the number of foreign substances (foreign substance number) having a size of 10 μm or more using an automatic defect charge coupled device (CCD) testing device (LCF-4015-RU, manufactured by Admon Science Inc.).

(Second Item: Evaluation of Film Lifting)

As the second item, evaluation of film lifting will be described. In this evaluation of film lifting, a laminate composed of a resin film obtained in each Example and a glass substrate was heated at 450° C. for 120 minutes after a SiO film having a thickness of 50 nm was formed on the resin film by CVD. Then, any film lifting of the SiO film from the resin film was observed visually and with an optical microscope. A film that exhibited no film lifting was rated as “acceptable”, and a film that exhibited any film lifting was rated as “unacceptable”.

(Third Item: Measurement of Sheet Resistance of Resin Film)

As the third item, measurement of the sheet resistance of a resin film will be described. In this measurement of sheet resistance, a resin film obtained in each Example was measured for sheet resistance by a guarded-electrode system in according with the Japanese Industrial Standards (JIS K 6271:2015) using a resistance measurement device (6517B, manufactured by Keithley Instruments, Inc.). Here, the measured face was that resin film face of the resin film which was not in contact with a glass substrate before the detachment (that is, the TFT-formed face). The electrode was produced from silver paste, wherein the main electrode diameter was 37 mm, the ring electrode width was 5.5 mm, the distance between the main electrode and the ring electrode was 1 mm, the counter electrode diameter was 55 mm, and the applied voltage was 500 V.

(Fourth Item: Measurement of Mechanical Strength of Resin Film)

As the fourth item, measurement of the mechanical strength of a resin film will be described. In this measurement of mechanical strength, a resin film obtained in each Example was measured for mechanical strength using a TENSILON universal material testing instrument (RTM-100, manufactured by Orientec Corporation) in accordance with the Japanese Industrial Standards (JIS K 7127:1999). The measurement conditions included a test piece width of 10 mm, a chuck-to-chuck distance of 50 mm, a testing speed of 50 mm/min, and the number of measurements, n, of 10.

(Fifth Item: Measurement of 1% Weight Decrease Temperature of Resin Film)

As the fifth item, measurement of the 1% weight decrease temperature of a resin film will be described. In this measurement, a resin film obtained in each Example was measured for 1% weight decrease temperature using a thermogravimetric analyzer (TGA-50, manufactured by Shimadzu Corporation). When this was done, the heating rate was 10° C./min.

(Sixth Item: Reliability Testing on TFT)

As the sixth item, reliability testing on TFT will be described. In this reliability testing, a TFT obtained in each Example was measured, using a semiconductor device analyzer (B1500A, manufactured by Agilent Technologies, Inc.), for variation ΔVth=Vth₁−Vth₀ between the initial threshold voltage Vth₀ and the threshold voltage Vth₁ after being driven one hour. A smaller value as ΔVth indicates that the reliability of the TFT is retained for a longer period of time. In this regard, the driving conditions for a TFT included a drain voltage Vd of 15 V, a source voltage Vs of 0 V, and a gate voltage Vg of 15 V.

(Seventh Item: Measurement of Arithmetic Mean Roughness of Resin Film)

As the seventh item, measurement of the arithmetic mean roughness of a resin film will be described. In this measurement, a laminate composed of a resin film obtained in each Example and a glass substrate was measured for arithmetic mean roughness Ra in accordance with the Japanese Industrial Standards (JIS B 0633:2001) using a surface texture measuring instrument (SURFCOM 1400D, manufactured by Tokyo Seimitsu Co., Ltd.). The measurement conditions included an evaluation length of 1.25 mm and a cutoff wavelength of 0.25 mm.

(Eighth Item: Measurement of Average Particle Diameter)

As the eighth item, measurement of the average particle diameter will be described.

In this measurement of the average particle diameter, the cross-section of a laminate composed of a resin film obtained in each Example and a glass substrate was exposed using an ion milling device (IB-09010CP, manufactured by JEOL Ltd.). Subsequently, the exposed cross-section was observed using a scanning electron microscope (S-4800, manufactured by Hitachi High-Technologies Corporation). The 50 particles observed in this cross-section were measured for the Feret's diameter in the film thickness direction of the resin film, and the arithmetic mean of the obtained measurement values was calculated to determine the average particle diameter of the electroconductive particles in the resin film.

(Compound)

In Examples and Comparative Examples, the below-mentioned compounds were suitably used. The compounds and abbreviations suitably used in Examples and Comparative Examples are as below-mentioned.
BPDA: 3,3′,4,4′-biphenyltetracarboxylic dianhydride
PDA: p-phenylene diamine
NMP: N-methyl-2-pyrrolidone
AD1: carbon black (MA100: manufactured by Mitsubishi Chemical Corporation)
AD2: carbon nanotubes (#698849: manufactured by Sigma-Aldrich Co. LLC.)
AD3: silver nanoparticles (#576832: manufactured by Sigma-Aldrich Co. LLC.)
AD4: tris(2,4-pentanedionato) iron (III)

### Example 1

In Example 1, a thermometer and a stirring rod equipped with stirring blades were fitted on a 2000-mL four-necked flask. Then, NMP (850 g) was added into the flask under a dry nitrogen gas stream, and heated to 60° C. After the resulting mixture was heated, PDA (40.91 g (378.3 mmol)) was added to the mixture with stirring, the dissolution of the PDA was verified, BPDA (109.09 g (370.8 mmol)) was added, and the resulting mixture was stirred for 12 hours. The reaction solution was cooled to room temperature, and then, AD1 (1.37 g) was added and dispersed using a bead mill. Finally, the resulting mixture was filtrated through a filter having a filter pore size of 2 μm to obtain varnish.

Subsequently, using a slit coating apparatus (manufactured by Toray Engineering Co., Ltd.), the varnish obtained as above-mentioned was applied onto a non-alkali glass substrate (AN-100, manufactured by Asahi Glass Co., Ltd.) having a size of 350 mm in length×300 mm in width×0.5 mm in thickness. Then, heating and vacuum-drying was performed at a temperature of 40° C. in the same apparatus. Finally, using a gas oven (INH-21CD, manufactured by Koyo Thermo Systems Co., Ltd.), heating was performed at 450° C. for 30 minutes in a nitrogen atmosphere (having an oxygen concentration of 100 ppm or less) to form a resin film having a film thickness of 10 μm on the glass substrate. A laminate composed of the obtained resin film and a glass substrate was used to carry out evaluation of the number of foreign substances by the above-mentioned first item method and carry out evaluation of film lifting by the above-mentioned second item method.

Subsequently, the glass substrate was immersed in hydrofluoric acid for four minutes to detach the resin film from the glass substrate, followed by air-drying the resin film. The obtained resin film was measured for sheet resistance by the above-mentioned third item method, measured for mechanical strength by the above-mentioned fourth item method, and measured for 1% weight decrease temperature by the above-mentioned fifth item method.

Subsequently, a SiO film was formed on the resin film by CVD before being detached from the glass substrate. Then, a TFT was formed on this SiO film. Specifically, a semiconductor layer in film form was formed, and this semiconductor layer was patterned into a predetermined shape by photolithography and etching. Subsequently, a gate insulation film was formed using a CVD method. Then, a gate electrode was formed and patterned on the gate insulation film, and this gate electrode was used as a mask to etch the gate insulation film, thus patterning the gate insulation film. Subsequently, an interlayer insulation film was formed, and then, contact holes were formed in the region opposing to a part of the semiconductor layer. Then, a pair of a source electrode and a drain electrode that were made of metal material were formed on this interlayer insulation film so as to fill the contact holes. Then, an interlayer insulation film was formed so as to cover these interlayer insulation film and a pair of a source electrode and a drain electrode, thus forming a TFT.

Finally, a laser (having a wavelength of 308 nm) was applied to that side of the glass substrate which did not have the resin film formed thereon, and the resin film was detached from the glass substrate along the interface therebetween. The TFT thus obtained was subjected to reliability testing by the above-mentioned sixth item method.

### Example 2

In Example 2, evaluation and the like were carried out in the same manner as in Example 1 except that the added amount of AD1 was changed to 0.068 g. In this regard, the added amount (0.068 g) of AD1 in Example 2 corresponds to 0.05 parts by mass with respect to 100 parts by mass of the heat-resistant resin in the resin film.

### Example 3

In Example 3, evaluation and the like were carried out in the same manner as in Example 1 except that the added amount of AD1 was changed to 3.42 g. In this regard, the added amount (3.42 g) of AD1 in Example 3 corresponds to 2.5 parts by mass with respect to 100 parts by mass of the heat-resistant resin in the resin film.

### Example 4

In Example 4, evaluation and the like were carried out in the same manner as in Example 1 except that AD1 was changed to AD2.

### Example 5

In Example 5, evaluation and the like were carried out in the same manner as in Example 1 except that AD1 was changed to AD3.

### Example 6

In Example 6, evaluation and the like were carried out in the same manner as in Example 1 except that AD1 was changed to AD4.

### Example 7

In Example 7, evaluation and the like were carried out in the same manner as in Example 1 except that the film thickness of the resin film was changed to 3 μm.

### Example 8

In Example 8, evaluation and the like were carried out in the same manner as in Example 1 except that the film thickness of the resin film was changed to 6 μm.

### Comparative Example 1

In Comparative Example 1, evaluation and the like were carried out in the same manner as in Example 1 except that AD1 was not added.

### Comparative Example 2

In Comparative Example 2, evaluation and the like were carried out in the same manner as in Example 1 except that the added amount of AD1 was changed to 0.0014 g. In this regard, the added amount (0.0014 g) of AD1 in Comparative Example 2 corresponds to 0.001 parts by mass with respect to 100 parts by mass of the heat-resistant resin in the resin film.

### Comparative Example 3

In Comparative Example 3, evaluation and the like were carried out in the same manner as in Example 1 except that the added amount of AD1 was changed to 7.2 g. In this regard, the added amount (7.2 g) of AD1 in Comparative Example 3 corresponds to 5 parts by mass with respect to 100 parts by mass of the heat-resistant resin in the resin film.

### Comparative Example 4

In Comparative Example 4, evaluation and the like were carried out in the same manner as in Example 1 except that AD1 was not added and that the film thickness of the resin film was changed to 3 μm.

The evaluation results obtained in the above-mentioned Examples 1 to 8 and Comparative Examples 1 to 4 are shown in Table 1 and Table 2.

TABLE 1

| Example | Example 1 | Example 2 | Example 3 | Example 4 | Example 5 | Example 6 | Example 7 | Example 8 |
|---|---|---|---|---|---|---|---|---|
| Additive | AD1 | AD1 | AD1 | AD2 | AD3 | AD4 | AD1 | AD1 |
| Added Amount (parts | 1 | 0.05 | 2.5 | 1 | 1 | 1 | 1 | 1 |
| by mass*) | | | | | | | | |
| Film Thickness (μm) | 10 | 10 | 10 | 10 | 10 | 10 | 3 | 6 |
| Sheet Resistance (Ω) | 2 × 10¹³ | 1 × 10¹⁵ | 4 × 10¹² | 7 × 10¹⁴ | 3 × 10¹³ | 2 × 10¹⁵ | 5 × 10¹³ | 4 × 10¹³ |
| Number of Foreign | 5 | 16 | 2 | 6 | 6 | 13 | 4 | 6 |
| Substances (pcs) | | | | | | | | |
| Film Lifting Test | acceptable | acceptable | acceptable | acceptable | acceptable | acceptable | acceptable | acceptable |
| Mechanical Strength | 375 | 410 | 360 | 379 | 371 | 392 | 310 | 362 |
| (MPa) | | | | | | | | |
| 1% Weight Decrease | 585 | 584 | 586 | 585 | 584 | 556 | 587 | 584 |
| Temperature (° C.) | | | | | | | | |
| ΔVth (V) | 0.1 | 0.2 | 0.1 | 0.1 | 1.2 | 1.3 | 0.1 | 0.1 |

*with respect to 100 parts by mass of heat-resistant resin

TABLE 2

| | Comparative Example | | | |
|---|---|---|---|---|
| | Comparative | Comparative | Comparative | Comparative |
| | Example 1 | Example 2 | Example 3 | Example 4 |
| Additive | — | AD1 | AD1 | — |
| Added Amount (parts by | 0 | 0.001 | 5 | 0 |
| mass*) | | | | |
| Film Thickness (μm) | 10 | 10 | 10 | 3 |
| Sheet Resistance (Ω) | 8 × 10¹⁶ | 6 × 10¹⁶ | 5 × 10¹¹ | 7 × 10¹⁶ |
| Number of Foreign | 68 | 65 | 6 | 73 |
| Substances (pcs) | | | | |
| Film Lifting Test | unacceptable | unacceptable | acceptable | unacceptable |
| Mechanical Strength (MPa) | 393 | 410 | 198 | 405 |
| 1% Weight Decrease | 583 | 581 | 580 | 583 |
| Temperature (° C.) | | | | |
| ΔVth (V) | 0.1 | 0.2 | evaluation not | 0.1 |
| | | | available** | |

*with respect to 100 parts by mass of heat-resistant resin
**evaluation not available for the leakage of TFT.

### Example 9

In Example 9, a laminate composed of a resin film before having a TFT formed thereon and of a glass substrate and obtained in the above-mentioned Example 1 was measured for the arithmetic mean roughness of the resin film by the above-mentioned seventh item method. Subsequently, the below-mentioned first to fourth recipes were carried out to measure the arithmetic mean roughness of the resin film again.

According to the first recipe, the resin film was polished by CMP using HS-J700-1 (a polishing liquid: manufactured by Hitachi Chemical Co., Ltd.), washed with water, and dried. According to the second recipe, the TFT-formed face of the resin film was irradiated with a laser using a laser emitter for a wavelength of 308 nm, and then, this resin film was washed with water and dried. When this was done, the laser was set to have a frequency of 300 Hz and an irradiation energy of 60 mJ. According to the third recipe, OFPR-800 (manufactured by Tokyo Ohka Kogyo Co., Ltd.) was applied to the resin film to have a film thickness of 2 μm, dried, and dry-etched using an RIE device so as to expose the resin film, and then, the resulting product was washed with water and dried. When this was done, the etching gas was O₂. In the fourth recipe, dry-etching, water-washing, and drying were carried out under the same conditions as in the third recipe except that the processes of applying and drying OFPR-800 were omitted.

In addition, the laminates before undergoing the above-mentioned first to fourth recipes and the laminates after undergoing the recipes were each measured for the average particle diameter of the electroconductive particles in the resin film by the above-mentioned eighth item method. The average particle diameters measured before performance of the first to fourth recipes, after performance of the first recipe, after performance of the second recipe, after performance of the third recipe, and after performance of the fourth recipe were 0.35 μm, 0.33 μm, 0.37 μm, 0.36 μm, and 0.33 μm respectively.

### Examples 10 to 16 and Comparative Examples 5 to 8

In Examples 10 to 16 and Comparative Examples 5 to 8, the laminates composed of a resin film and a glass substrate and obtained in Examples 1 to 8 and Comparative Examples 1 to 4 were each used to evaluate the arithmetic mean roughness of the resin film in the same manner as in Example 9, as shown in Table 3 and Table 4.

The evaluation results obtained in the above-mentioned Examples 9 to 16 and Comparative Examples 5 to 8 are shown in Table 3 to Table 4. In this regard, the “surface roughness” in Tables 3 and 4 is the arithmetic mean roughness of the resin film measured by the above-mentioned seventh item method.

TABLE 3

| Example | | Example 9 | Example 10 | Example 11 | Example 12 | Example 13 | Example 14 | Example 15 | Example 16 |
|---|---|---|---|---|---|---|---|---|---|
| Laminate composed of | | Example 1 | Example 2 | Example 3 | Example 4 | Example 5 | Example 6 | Example 7 | Example 8 |
| resin film and glass | | | | | | | | | |
| substrate | | | | | | | | | |
| Surface | Initial | 30 | 12 | 50 | 28 | 31 | 4 | 32 | 29 |
| Roughness | Value | | | | | | | | |
| (nm) | 1. CMP | 8 | 6 | 9 | 7 | 12 | 7 | 8 | 8 |
| | 2. Laser | 7 | 5 | 9 | 8 | 12 | 5 | 8 | 8 |
| | Irradiation | | | | | | | | |
| | 3. Resist | 6 | 4 | 7 | 6 | 10 | 4 | 7 | 7 |
| | Coating, | | | | | | | | |
| | Dry-etching | | | | | | | | |
| | 4. Dry- | 29 | 13 | 49 | 29 | 30 | 6 | 30 | 28 |
| | etching | | | | | | | | |
| | only | | | | | | | | |

TABLE 4

| | | Comparative Example | | | |
|---|---|---|---|---|---|
| | | Comparative | Comparative | Comparative | Comparative |
| | | Example 5 | Example 6 | Example 7 | Example 8 |
| Laminate composed of resin | | Comparative | Comparative | Comparative | Comparative |
| film and glass substrate | | Example 1 | Example 2 | Example 3 | Example 4 |
| Surface | Initial Value | 4 | 8 | 71 | 5 |
| Roughness | 1. CMP | 7 | 9 | 30 | 9 |
| (nm) | 2. Laser | 5 | 7 | 22 | 8 |
| | Irradiation | | | | |
| | 3. Resist | 4 | 5 | 15 | 5 |
| | Coating, | | | | |
| | Dry-etching | | | | |
| | 4. Dry- | 5 | 9 | 69 | 6 |
| | etching only | | | | |

### Examples 17 to 48

In Examples 17 to 48, evaluation and the like were carried out in the same manner as in Example 1 except that, in place of the above-mentioned laminate composed of a resin film and a glass substrate and obtained in Example 1, the laminate composed of a resin film and a glass substrate and allowed to undergo each of the first to fourth recipes in each of Examples 9 to 16 was used, as shown in Table 5 to Table 8. The evaluation results of Examples 17 to 48 are shown in Tables 5 to 8. In the “Recipe” row in each of Tables 5 to 8, “1.” means the first recipe, “2.” means the second recipe, “3.” means the third recipe, and “4.” means the fourth recipe.

TABLE 5

| Example | Example 17 | Example 18 | Example 19 | Example 20 | Example 21 | Example 22 | Example 23 | Example 24 |
|---|---|---|---|---|---|---|---|---|
| Laminate composed | Example 9 | Example 10 | Example 11 | Example 12 | Example 13 | Example 14 | Example 15 | Example 16 |
| of resin film and | | | | | | | | |
| glass substrate | | | | | | | | |
| Recipe | 1. | 1. | 1. | 1. | 1. | 1. | 1. | 1. |
| Film Thickness (μm) | 10 | 10 | 10 | 10 | 10 | 10 | 3 | 6 |
| Sheet Resistance (Ω) | 1 × 10¹³ | 1 × 10¹⁵ | 3 × 10¹² | 6 × 10¹⁴ | 3 × 10¹³ | 3 × 10¹⁵ | 4 × 10¹³ | 5 × 10¹³ |
| Number of Foreign | 6 | 18 | 4 | 5 | 7 | 11 | 6 | 8 |
| Substances (pcs) | | | | | | | | |
| Film Lifting Test | acceptable | acceptable | acceptable | acceptable | acceptable | acceptable | acceptable | acceptable |
| Mechanical Strength | 370 | 405 | 355 | 375 | 360 | 380 | 305 | 348 |
| (MPa) | | | | | | | | |
| 1% Weight Decrease | 585 | 585 | 586 | 584 | 585 | 558 | 588 | 582 |
| Temperature (° C.) | | | | | | | | |
| ΔVth (V) | 0.2 | 0.1 | 0.1 | 0.2 | 1.3 | 1.4 | 0.1 | 0.2 |

TABLE 6

| Example | Example 25 | Example 26 | Example 27 | Example 28 | Example 29 | Example 30 | Example 31 | Example 32 |
|---|---|---|---|---|---|---|---|---|
| Laminate composed | Example 9 | Example 10 | Example 11 | Example 12 | Example 13 | Example 14 | Example 15 | Example 16 |
| of resin film and | | | | | | | | |
| glass substrate | | | | | | | | |
| Recipe | 2. | 2. | 2. | 2. | 2. | 2. | 2. | 2. |
| Film Thickness (μm) | 10 | 10 | 10 | 10 | 10 | 10 | 3 | 6 |
| Sheet Resistance (Ω) | 3 × 10¹³ | 1 × 10¹⁵ | 6 × 10¹² | 8 × 10¹⁴ | 1 × 10¹³ | 3 × 10¹⁵ | 6 × 10¹³ | 5 × 10¹³ |
| Number of Foreign | 3 | 19 | 1 | 4 | 8 | 14 | 3 | 7 |
| Substances (pcs) | | | | | | | | |
| Film Lifting Test | acceptable | acceptable | acceptable | acceptable | acceptable | acceptable | acceptable | acceptable |
| Mechanical Strength | 376 | 402 | 355 | 370 | 369 | 386 | 308 | 370 |
| (MPa) | | | | | | | | |
| 1% Weight Decrease | 586 | 586 | 587 | 586 | 584 | 553 | 587 | 586 |
| Temperature (° C.) | | | | | | | | |
| ΔVth (V) | 0.1 | 0.1 | 0.1 | 0.2 | 1.3 | 1.3 | 0.2 | 0.1 |

TABLE 7

| Example | Example 33 | Example 34 | Example 35 | Example 36 | Example 37 | Example 38 | Example 39 | Example 40 |
|---|---|---|---|---|---|---|---|---|
| Laminate composed | Example 9 | Example 10 | Example 11 | Example 12 | Example 13 | Example 14 | Example 15 | Example 16 |
| of resin film and | | | | | | | | |
| glass substrate | | | | | | | | |
| Recipe | 3. | 3. | 3. | 3. | 3. | 3. | 3. | 3. |
| Film Thickness (μm) | 10 | 10 | 10 | 10 | 10 | 10 | 3 | 6 |
| Sheet Resistance (Ω) | 2 × 10¹³ | 2 × 10¹⁵ | 3 × 10¹² | 6 × 10¹⁴ | 4 × 10¹³ | 2 × 10¹⁵ | 6 × 10¹³ | 2 × 10¹³ |
| Number of Foreign | 6 | 15 | 4 | 5 | 5 | 11 | 5 | 7 |
| Substances (pcs) | | | | | | | | |
| Film Lifting Test | acceptable | acceptable | acceptable | acceptable | acceptable | acceptable | acceptable | acceptable |
| Mechanical Strength | 377 | 412 | 350 | 390 | 380 | 388 | 301 | 364 |
| (MPa) | | | | | | | | |
| 1% Weight Decrease | 596 | 585 | 587 | 586 | 584 | 560 | 589 | 580 |
| Temperature (° C.) | | | | | | | | |
| ΔVth (V) | 0.1 | 0.1 | 0.1 | 0.1 | 1.4 | 1.7 | 0.2 | 0.2 |

TABLE 8

| Example | Example 41 | Example 42 | Example 43 | Example 44 | Example 45 | Example 46 | Example 47 | Example 48 |
|---|---|---|---|---|---|---|---|---|
| Laminate composed | Example 9 | Example 10 | Example 11 | Example 12 | Example 13 | Example 14 | Example 15 | Example 16 |
| of resin film and | | | | | | | | |
| glass substrate | | | | | | | | |
| Recipe | 4. | 4. | 4. | 4. | 4. | 4. | 4. | 4. |
| Film Thickness (μm) | 9 | 9 | 9 | 9 | 9 | 9 | 2 | 5 |
| Sheet Resistance (Ω) | 2 × 10¹³ | 1 × 10¹⁵ | 4 × 10¹² | 7 × 10¹⁴ | 3 × 10¹³ | 2 × 10¹⁵ | 5 × 10¹³ | 4 × 10¹³ |
| Number of Foreign | 5 | 16 | 2 | 6 | 6 | 13 | 4 | 6 |
| Substances (pcs) | | | | | | | | |
| Film Lifting Test | acceptable | acceptable | acceptable | acceptable | acceptable | acceptable | acceptable | acceptable |
| Mechanical Strength | 360 | 401 | 349 | 360 | 355 | 370 | 265 | 330 |
| (MPa) | | | | | | | | |
| 1% Weight Decrease | 586 | 586 | 587 | 584 | 586 | 557 | 586 | 585 |
| Temperature (° C.) | | | | | | | | |
| ΔVth (V) | 0.2 | 0.1 | 0.2 | 0.2 | 1.4 | 1.6 | 0.2 | 0.1 |

### Example 49

In Example 49, a TFT was formed, by the method described in Example 1, using a laminate composed of a resin film before having a TFT formed thereon and of a glass substrate and obtained in the above-mentioned Example 1 and using the laminates composed of a resin film and a glass substrate and obtained in the above-mentioned Example 9 (four types: which each underwent each of the above-mentioned first to fourth recipes). Subsequently, before the resin film was detached from the glass substrate, the first electrode composed of ITO was connected to the wiring for further formation. Then, the surface was coated with a resist, prebaked, exposed to light through a desired patterned mask, and developed. Using this resist pattern as mask, patterning was performed by wet-etching with an ITO etchant. Subsequently, the resist pattern was removed using a resist stripping liquid (a liquid mixture of monoethanol amine and diethylene glycol monobutyl ether). After the resist pattern was detached, the substrate was washed with water and heated for dehydration to provide an electrode substrate having a planarizing film. Next, an insulation film was formed in a shape that covers the periphery of the first electrode.

In addition, in a vacuum deposition apparatus, a positive hole transport layer, organic luminescent layer, and electron transport layer were deposited in this order through desired pattern masks. Subsequently, the second electrode composed of stacked layers of aluminium and magnesium (Al/Mg) was formed over the entire surface above the substrate. In addition, a sealing film in the form of stacked layers of SiO and SiN was formed by CVD. Finally, a laser (having a wavelength of 308 nm) was applied to that side of the glass substrate which did not have the resin film formed thereon, and the resin film was detached from the glass substrate along the interface therebetween to thereby obtain an organic EL display.

Subsequently, this obtained organic EL display was energized to emit light by applying a voltage through a driving circuit. When this was done, observations were made of the generation ratio of non-light-emitting pixels called dark spots and constantly light-emitting pixels called bright spots with respect to all pixels of the organic EL display. A generation ratio of 1% or less for both of these combined together was rated as level A. As this generation ratio, a generation ratio of more than 1% and 5% or less was rated as level B, a generation ratio of more than 5% and 10% or less was rated as level C, and a generation ratio of more than 10% was rated as level D. These levels A to D show how good the evaluation results of the organic EL displays are; level A means “excellent”; and levels B, C, and D mean the evaluation results poorer in this order. The meanings of these levels A to D for the evaluation results are the same for the other evaluation results.

Subsequently, a 5 mm metal column was fixed along the central portion of the organic EL display, which underwent a bending action so as to make a holding angle in the range of from 0° (the sample being a flat plane) to 180° (the sample being bent back around the column) with this metal column in such a manner that the light-emitting side of the organic EL display faced outward. After this bending action, the organic EL display was allowed to emit light again, and the generation ratio of bright spots and dark spots was observed. An increase caused in the generation ratio by the bending action carried out once was rated as level D, an increase caused in the generation ratio by the bending action carried out two to three times was rated as level C, an increase caused in the generation ratio by the bending action carried out four to six times was rated as level B, and an increase caused in the generation ratio by the bending action carried out seven to nine times was rated as level A. In addition, no increase caused in the generation ratio by the bending action carried out ten times was rated as level S. Level S means that the evaluation results are “the best (better than level A)”.

### Example 50

In Example 50, evaluation and the like were carried out in the same manner as in Example 49 except that the laminate composed of a resin film and a glass substrate was changed to the following laminate and used. The laminate to be evaluated in Example 50 was a laminate that was composed of a resin film and a glass substrate and obtained by carrying out the below-mentioned fifth recipe on the laminate composed of a resin film before having a TFT formed thereon and of a glass substrate and obtained in the above-mentioned Example 1. In this regard, the laminate composed of a resin film and a glass substrate and obtained by carrying out the fifth recipe was measured for the arithmetic mean roughness of the resin film by the above-mentioned seventh item method, with the result that this arithmetic mean roughness was 50 nm.

In the fifth recipe, TPE3000 (manufactured by Toray Engineering Co., Ltd.) as a polyimide etching liquid was used for etching treatment at a temperature of 60° C. for one minute, followed by water-washing and drying.

### Comparative Example 9

In Comparative Example 9, evaluation and the like were carried out in the same manner as in Example 49 except that the laminates composed of a resin film and a glass substrate were changed to: the laminate composed of a resin film before having a TFT formed thereon and of a glass substrate and obtained in the above-mentioned Comparative Example 1; and the four types of laminates composed of a resin film and a glass substrate and obtained in the above-mentioned Comparative Example 5 (those which each underwent each of the above-mentioned first to fourth recipes).

### Comparative Example 10

In Comparative Example 10, evaluation and the like were carried out in the same manner as in Example 49 except that the laminate composed of a resin film and a glass substrate was changed to the laminate that was composed of a resin film and a glass substrate and obtained by carrying out the above-mentioned fifth recipe on the laminate composed of a resin film before having a TFT formed thereon and of a glass substrate and obtained in the above-mentioned Comparative Example 1. In this regard, the laminate composed of a resin film and a glass substrate and obtained by carrying out the fifth recipe was measured for the arithmetic mean roughness of the resin film by the above-mentioned seventh item method, with the result that this arithmetic mean roughness was 20 nm.

The evaluation results obtained in the above-mentioned Example 49, Example 50, Comparative Example 9, and Comparative Example 10 are shown in Table 9.

TABLE 9

| | | | | | How many times bending | |
|---|---|---|---|---|---|---|
| | | | Generation Ratio | | was repeated to | |
| | Laminate composed of resin film | | of Dark Spots and | | increase dark spots | |
| Example | and glass substrate | | Bright Spots (%) | Rating | and bright spots | Rating |
| Example 49 | Example 1 | | 15 | D | 2 | C |
| | Example 9 | 1. CMP | 4 | B | 7 | A |
| | | 2. Laser Irradiation | 3 | B | 8 | A |
| | | 3. Resist Coating, | 1 | A | 10< | S |
| | | Dry-etching | | | | |
| | | 4. Dry-etching only | 17 | D | 2 | C |
| Example 50 | Example ⅕. Polyimide Etching | | 25 | D | 1 | D |
| Comparative | Comparative Example 1 | | 18 | D | 10< | S |
| Example 9 | Comparative | 1. CMP | 16 | D | 10< | S |
| | Example 5 | 2. Laser Irradiation | 19 | D | 10< | S |
| | | 3. Resist Coating, | 17 | D | 10< | S |
| | | Dry-etching | | | | |
| | | 4. Dry-etching only | 19 | D | 10< | S |

| | | | | | |
|---|---|---|---|---|---|
| Comparative | Comparative Example ⅕. | 27 | D | 8 | A |
| Example 10 | Polyimide Etching | | | | |

### INDUSTRIAL APPLICABILITY

As above-mentioned, a resin film, a display including the same, and a method of producing them, all according to the present invention, are suitable for: a resin film that is less likely to have foreign substances stuck thereto and is suitable for a TFT support substrate; and a display using such a resin film.

1. A resin film to be used as a support substrate of a thin film transistor, comprising
a heat-resistant resin,
wherein a predetermined resin film face of said resin film has a sheet resistance of more than 1×10¹²Ω and less than 1×10¹⁶Ω.

2. The resin film according to claim 1, further comprising electroconductive particles.

3. The resin film according to claim 2, wherein said electroconductive particles are carbon particles.

4. The resin film according to claim 2, wherein the amount of the electroconductive particles is 0.01 parts by mass or more and 3 parts by mass or less with respect to 100 parts by mass of said heat-resistant resin.

5. The resin film according to claim 1, wherein said resin film has a film thickness of 4 μm or more and 40 μm or less.

6. The resin film according to claim 1, wherein said predetermined resin film face has an arithmetic mean roughness of 10 nm or less.

7. A display comprising said resin film according to claim 1.

8. A method of producing a resin film for producing said resin film according to claim 1, said method comprising:
a coating step of coating a support with a resin composition containing a heat-resistant resin or a precursor of said heat-resistant resin and a solvent; and
a heating step of heating a coating film obtained by said coating step, to obtain a resin film.

9. The method of producing a resin film according to claim 8, comprising a polishing step of polishing the heated resin film.

10. The method of producing a resin film according to claim 8, comprising an irradiating step of irradiating said heated resin film with a laser.

11. The method of producing a resin film according to claim 8, comprising:
a resist coating step of coating the heated resin film with a resist to form a laminate of said resin film on said support and said resist covering said resin film; and
an etching step of dry-etching the resist-coated side of the obtained laminate to expose said resin film.

12. A method of producing a display, comprising:
a film-producing step of producing a resin film on a support by said method of producing a resin film according to claim 8;
an element-forming step of forming a thin film transistor element on said resin film; and
a detaching step of detaching, from said support, said resin film having said thin film transistor element formed thereon.
